(19) United States
(12) Patent Application Publication
(10) Pub. No.: US 2007/0187821 A1
(43) Pub. Date: Aug. 16, 2007

(54) Chip with bump structure

(76) Inventors: Ming-Ling Ho, Hsin-Chu (TW); Chun-Ping Hu, Hsin-Chu (TW); Chien-Wen Tsai, Hsin-Chu (TW)

Correspondence Address: G. LINK CO.,LTD, 3550 Bell Road, MINOOKA, IL, 60447, US

(21) Appl. No.: 11/353,061

(22) Filed: Feb. 14, 2006

(51) Int. Cl. H01L 23/48

(52) U.S. Cl. 257/737

(57) ABSTRACT

A chip with a bump structure comprises a chip, a plurality of pads and a plurality of bumps. The chip includes a microcircuit fabricated by integrated circuit technique. The pads are metallized portions of the chip for electrical connection. The bumps are metal bulges on the pads of the chip for electrically connecting the pads with the terminals of other components. The bumps are arranged in a horizontal direction, and each of the bumps include a first section and a second section, wherein the first section and the second section are electrically connected to each other along a vertical direction. The first section electrically contacts the corresponding pad. The size of the second section in the horizontal direction is larger than that of the first section. The second section is used for electrically connecting the chip to other components. The first section and the second section of adjacent bumps are interlaced.

### FIELD OF THE INVENTION

The present invention relates to a chip having a bump structure, and more particularly, to a structure of bumps that includes metal terminals for the electrical connections of the chip.

### BACKGROUND OF THE INVENTION

For conventional chips with bumps using for integrated circuit (IC), chips include metallized portions formed by semiconductor processes for electrically outputting/inputting bonding pads thereof, and bumps are electrically connected to the metallized portions for outputting/inputting the same. In order to accommodate to the probes in chip test systems or bonding wire devices in chip package processes, bumps of such chips usually have large flat areas for ensuring the reliabilities during testing or wiring. However, the chip size becomes smaller due to the development of semiconductor technology. The distances between the bonding pads thus become closer to fabricate the minimized chips. Unfortunately, the sizes of chips are limited by test instruments and wire bonding devices. Therefore, an improved bump structure that reduces the areas of chips is provided by the applicants to overcome the aforesaid disadvantages.

### SUMMARY OF THE INVENTION

It is the primary object of the invention to provide a chip with a bump structure that serves as electrical terminals for the chip.

It is another object of the invention to provide a chip with a bump structure, in which bumps for electrical input/output of the chip are arranged compactly.

In accordance with the objects of the invention, a chip having a bump structure is provided. The structure comprises a chip, a plurality of pads and a plurality of bumps. The chip includes a microcircuit manufactured by integrated circuit technique. The pads are metallized portions of the chip for electrical connections. The bumps are metal bulges on the pads of the chip for electrically connecting the pads with terminals of other components. The bumps are arranged in a horizontal direction, and each of the bumps includes a first section and a second section, wherein the first section and the second section are electrically connected to each other along a vertical direction. The first section electrically contacts the pad. The size of the second section in the horizontal direction is larger than that of the first section. The second section is used for electrically connecting the chip to other components. The first section and the second section of adjacent bumps are interlaced.

Additionally, the bump may include a strip-shaped first section and a circular second section, which are electrically connected with each other. Alternatively, the bump may be a trapezoid form, part of which is defined as the first section and the second section.

### BRIEF DESCRIPTION OF THE DRAWINGS

The foregoing aspects, as well as many of the attendant advantages and features of this invention will become more apparent by reference to the following detailed description, when taken in conjunction with the accompanying drawings, wherein:

FIG. 1 illustrates a cross-sectional view of a chip with a bump structure according to one embodiment of the invention;

FIG. 2 illustrates a top view of a chip with a bump structure according to one embodiment of the invention;

FIG. 3 illustrates a top view of a chip with a bump structure according to another embodiment of the invention; and

FIG. 4 illustrates a top view of a chip with a bump structure according to another embodiment of the invention.

### DETAILED DESCRIPTION OF THE INVENTION

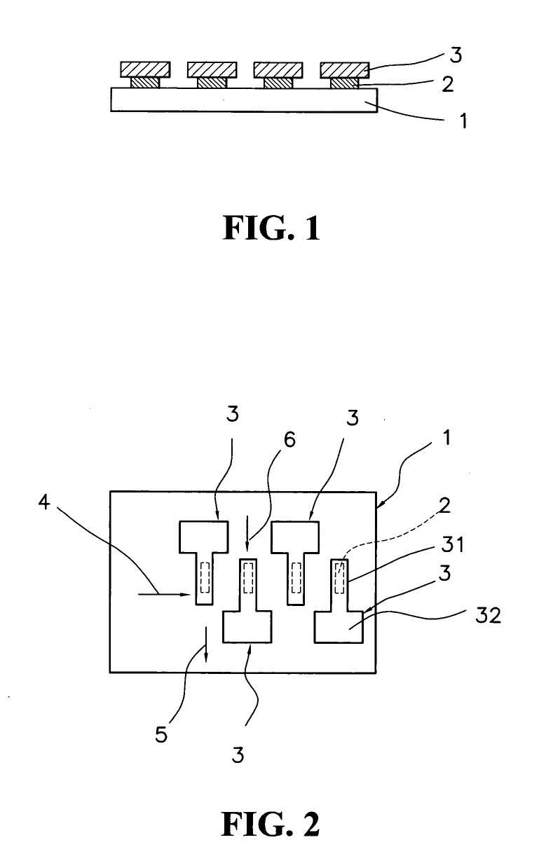

FIG. 1 illustrates a cross-sectional view of a chip with a bump structure according to one embodiment of the invention, and FIG. 2 illustrates a top view of a chip with a bump structure according to one embodiment of the invention. Referring to FIG. 1 and FIG. 2, protruded bumps 3 are formed corresponding to pads 2 on a chip 1. The chip 1 is positioned on the same substrate, and constitute microcircuits with specific circuitry by means of integrated circuit techniques. The pads 2 are metallized portions on the chip 1 for electrical connection. The bumps 3 are metal bulges formed on the pads 2 of the chip 1 for electrically coupling pads 2 with other components. In one embodiment, the bumps 3 are gold bumps.

The aforesaid bumps 3 are arranged in a horizontal direction 4. Each of the bumps 3 includes a first section 31 and a second section 32. The first section 31 and the second section 32 are electrically connected to each other. The first section 31 electrically contacts the corresponding pad 2 of the chip 1. The size of the second section 32 in the horizontal direction 4 is larger than that of the first section 31. The second section 32 is used to connect the chip 1 to terminals of other components. For example, the second section 32 is electrically connected with other components through bonding wire. A first vertical direction 5 is defined from the first section 31 to the second section 32, and a second vertical direction 6 is defined from the second section 32 to the first section 31. The first vertical direction 5 and the second vertical direction 6 are perpendicular to the horizontal direction 4, and the first sections 31 and the second sections 32 of adjacent bumps 3 are interlaced. Hence, the adjacent bumps 3 are interlaced in the first vertical direction 5 and the second vertical direction 6. According to the deployment of the first sections 31 and the second sections 32 of the bumps 3, the interval between the bumps 3 is closer in such a way that the area of the chip is reduced.

Each of the bumps 3 includes a smaller horizontal size at one end along the vertical direction, and a larger horizontal size at the other end. Two ends of the bumps 3 separately with relatively small size and large size are reversed, so as to compact the arrangement of the bumps 3. Consequently, bumps 3 occupy less flat space, and the area of the chip 1 is reduced.

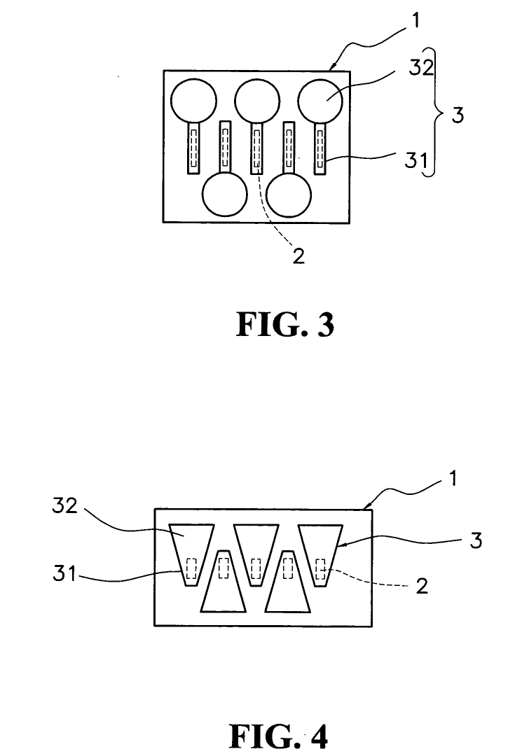

FIG. 3 illustrates a top view of a chip with a bump structure according to another embodiment of the invention. Based on the aforementioned concept, the bump 3 may include a strip-shaped first section 31 and a circular second section 32, which are electrically connected with each other as shown in FIG. 3. Furthermore, the design of the second section 32 may have other geometries with different widths on its top and bottom, such as a rectangular-shaped or an inverted T-shaped profile.

FIG. 4 illustrates a top view of a chip with a bump structure according to another embodiment of the invention. Referring to FIG. 4, the shape of the bump 3 may be trapezoid that is composed of the first section 31 and the second section 32.

Moreover, the embodiments described above are exemplars only, and those skilled in the art may modify the profiles of the first sections 31 and the second sections 32 of the bumps 3, which will not depart from the scope of the invention.

While the invention has been particularly shown and described with reference to the preferred embodiments thereof, these are, of course, merely examples to help clarify the invention and are not intended to limit the invention. It will be understood by those skilled in the art that various changes, modifications, and alterations in form and details may be made therein without departing from the spirit and scope of the invention, as set forth in the following claims.

1. A chip with a bump structure comprising:
a chip providing a microcircuit;
a plurality of metallic pads being attached to a facial side of the chip for electrical connection; and
flat metallic bump being disposed on top of the respective pad for the pads being capable of electrically connecting with terminals of other components;
wherein each of the bumps provides a first section and a second section, which extends from the first section, the bottom side of the first section of the respective bump electrically contacts the respective pad, and the second section of the respective bump is larger than said first section in size for electrically connecting with the terminals of other components such that said second section is disposed in a way of interlacing to each other alternately.

2. The chip with the bump structure of claim 1, wherein the first section is strip shape and the second section is rectangular shape.

3. The chip with the bump structure of claim 1, wherein the first section is strip shape and the second section is circular shape.

4. The chip with the bump structure of claim 1, wherein the first section and the second section form a trapezoidal shape such that the respective bump is disposed in a way of being opposite to each other alternately.

5. (canceled)
